(19) United States
(12) Patent Application Publication
(10) Pub. No.: US 2025/0147561 A1
(43) Pub. Date: May 8, 2025

(54) Vapor Chamber with an Extended Base Plate

(71) Applicant: Google LLC, Mountain View, CA (US)

(72) Inventors: Tyler Jon Ewing, Menlo Park, CA (US); Joseph Allore, Mundelein, IL (US); Michael J. Lombardi, South Barrington, IL (US)

(73) Assignee: Google LLC, Mountain View, CA (US)

(21) Appl. No.: 19/018,604

(22) Filed: Jan. 13, 2025

Related U.S. Application Data
(60) Provisional application No. 63/740,856, filed on Dec. 31, 2024.

(51) Int. Cl. G06F 1/20; H05K 7/20

(52) U.S. Cl. CPC G06F 1/203; H05K 7/20336

(57) ABSTRACT

This document describes an electronic device with a chassis and a vapor chamber positioned within the chassis. The vapor chamber includes a base plate and a cap portion attached to the base plate to form a sealed chamber. The base plate extends outward beyond the sealed chamber to form an extended portion with a first edge attached to a sidewall of the chassis and a second edge, in the form of a mechanical flange, connected to the chassis. The base plate with the extended portion forms the floor of a battery compartment within the chassis and provides a thermal path between the vapor chamber and the chassis. By integrating the vapor chamber into the structural components, the need for a separate mid-plate is eliminated, allowing for a thinner device that efficiently dissipates heat while maintaining structural rigidity.

### CROSS-REFERENCE TO RELATED APPLICATION(S)

This application claims the benefit of U.S. Provisional Patent Application Ser. No. 63/740,856 filed on Dec. 31, 2024, the disclosure of which is incorporated by reference herein in its entirety.

### SUMMARY

This document describes techniques, systems, and apparatuses for integrating a vapor chamber with an extended base plate to an electronic device. The electronic device includes a chassis and a vapor chamber positioned within the chassis for enhanced thermal management and structural support. The vapor chamber includes a base plate and a cap portion attached to the base plate to form a sealed chamber. The base plate extends outward beyond the sealed chamber to form an extended portion. The extended portion includes a first edge configured to be attached to a sidewall of the chassis and a second edge, adjacent to the first edge, in the form of a mechanical flange configured to be connected to the chassis. The base plate including the extended portion forms the floor of a battery compartment within the chassis and provides a thermal path between the vapor chamber and the chassis.

By integrating the vapor chamber with the extended base plate into the structural components of the electronic device, a reliance on a conventional and separate mid-frame or mid-plate design is obviated, reducing the overall thickness of the electronic device and allowing for increased battery capacity. The base plate may be made from stainless steel sheet metal, and the cap portion may be attached to the base plate by welding. In some implementations, a graphite layer is applied to at least a portion of the base plate to enhance thermal conductivity.

The base plate is electrically connected to the chassis to provide grounding for the electronic device and forms a mid-plate ground for at least one antenna adjacent to the base plate. The vapor chamber is positioned between a battery and a display within the chassis. In some implementations, the extended portion of the base plate includes a designated area configured to receive an under-display fingerprint sensor, providing a gap between the battery and the sensor.

This Summary is provided to introduce simplified concepts for integrating the vapor chamber with the extended base plate into the chassis of an electronic device, which are further described below in the Detailed Description and illustrated in the Drawings. This Summary is intended neither to identify essential features of the claimed subject matter nor for use in determining the scope of the claimed subject matter.

### BRIEF DESCRIPTION OF THE DRAWINGS

The details of one or more implementations of a vapor chamber with an extended base plate within an electronic device are described in this document with reference to the following drawings. The use of the same numbers in different instances may indicate similar features or components:

FIG. 1A is a front perspective view of an example electronic device with a chassis detached from a vapor chamber.

FIG. 1B is a rear perspective view of the example electronic device shown in FIG. 1A with the chassis detached from the vapor chamber.

FIG. 1C is a rear perspective view of the example electronic device shown in FIG. 1A with the vapor chamber attached to the chassis, forming a floor of a battery compartment.

FIG. 2A is a perspective view of the example electronic device showing the base plate of the vapor chamber forming the floor of the battery compartment.

FIG. 2B is a front view of the example electronic device shown in FIG. 2A, illustrating the vapor chamber forming a floor of a display module.

FIG. 2C is a rear view of the example electronic device shown in FIG. 2A, depicting the extended portion of the base plate and a plurality of flexible connectors forming the floor of the battery compartment.

FIG. 3 is a side sectional view along the width of the example electronic device.

FIG. 3A is an enlarged view of section A of the example electronic device shown in FIG. 3.

FIG. 3B is an enlarged view of section B of the example electronic device shown in FIG. 3.

FIG. 3C is an enlarged view of section C of the example electronic device shown in FIG. 3.

FIG. 4 is a perspective view of a bottom portion of the example electronic device, showing a part of the chassis and the base plate attached to the vapor chamber.

FIG. 4A is a sectional view along section A-A′ of the example electronic device shown in FIG. 4.

FIG. 5 is a perspective view of a bottom portion of the example electronic device, showing a part of the chassis and the base plate attached to the vapor chamber.

FIG. 5A is a sectional view along section A-A′ of the example electronic device shown in FIG. 5.

FIG. 6 is a diagram of example electronic devices in which a vapor chamber with the extended base plate can be implemented.

### DETAILED DESCRIPTION

### Overview

Portable electronic devices such as smartphones and laptops have become ubiquitous for consumers, providing communication and access to information and entertainment in a single device. Once considered a luxury, electronic devices have gradually evolved from bulky unreliable gadgets with a few features to powerful instruments that fit comfortably in tiny spaces. The drive to improve the design of electronic device has led to technological advancements such as increased processing power, advanced cameras, and high-quality screens. Components that enable these advancements, however, often generate heat that can damage the electronic device or themselves. This heat may be dissipated by employing thermal management components, but these components often increase the thickness and cost of electronic devices.

More specifically, making electronic devices thinner without sacrificing device performance is a complex undertaking. For example, a printed circuit board (PCB) of a smartphone may include one or more processing elements with miniaturized components that attempt to reduce the size and thus, the overall thickness of the smartphone. The resulting smaller form factor, however, can produce a noticeable lack of internal space that not only increases the importance of thermal management components but also creates new difficulties for thermal management. As electronic devices incorporate powerful processors and high-performance components into smaller spaces, thermal management becomes a component of the design. Operations such as running applications and streaming videos produce heat, which may be dissipated with components such as heat sinks, thermal conductive materials, and graphene sheets.

In some battery chassis architectures, a mid-frame is removed to help optimize for battery capacity. Since vapor chambers are typically mounted to mid-frames, the absence of a mid-frame produces new design challenges that may affect the operations of the electronic device. For example, having a vapor chamber floating in a battery area of an electronic device may introduce thermal regression since heat dissipation is reduced.

To this end, the illustrative examples disclose improving thermal management and structural integrity for electronic devices by embedding a vapor chamber in a high-thermal-conductivity base plate. More specifically, the illustrative examples disclose integrating thermal management components into the structural design of electronic devices. A vapor chamber including an extended base plate region, which also acts as a middle plate, is configured to fit within the chassis and provide effective heat dissipation and structural support. The extended base plate, comprising high thermal conductivity metals, may be stamped on at least one side of a cap portion to produce a large vapor chamber area. The vapor chamber includes a coolant that undergoes phase changes to move heat away from electronic components while maintaining a slim profile.

Techniques and systems described herein make use of specialized attachment mechanisms such as laser welding or specialized molding techniques to integrate the extended base plate and cap portion, or a middle frame of the chassis and middle plate formed by the extended base plate, into a single structure that can support mechanical and thermal functions.

The following discussion describes operating environments and techniques that may be employed in the operating environments and example methods. Although systems and techniques directed at an integrated vapor chamber for electronic devices are described, it is to be understood that the subject of the appended Claims is not necessarily limited to the specific features or methods described. Rather, the specific features and methods are disclosed as example implementations and reference is made to the operating environment by way of example only.

### Example Environment

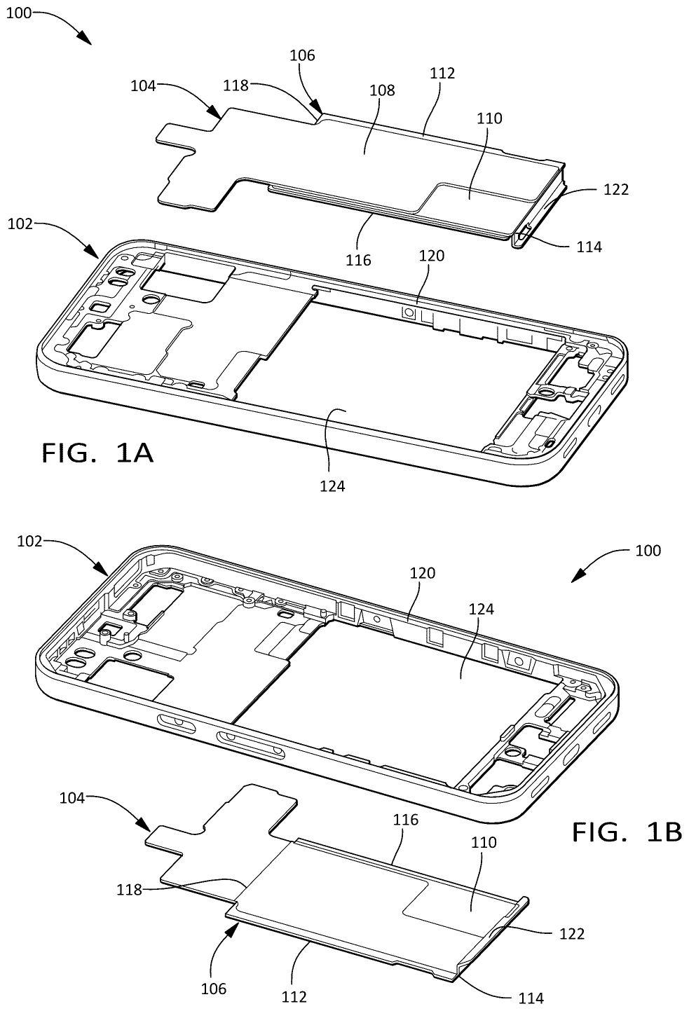

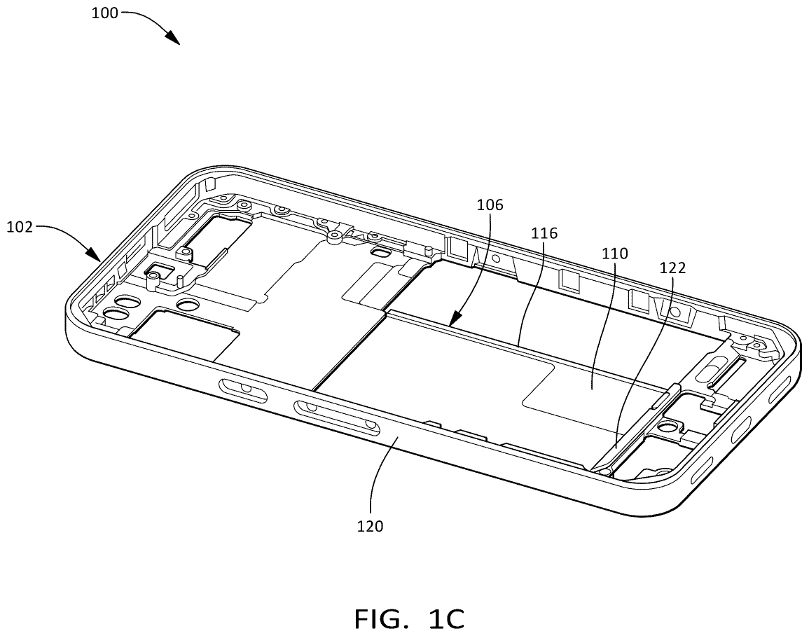

FIG. 1 illustrates a front perspective view of an example electronic device 100 (e.g., a smartphone) comprising a chassis 102 for housing several components of the electronic device 100 such as a processor, a display, a battery, one or more antennas, and a variety of sensors. The example electronic device 100 further includes a vapor chamber 104 (shown as being detached from the chassis 102) which is configured to be attached to the chassis 102 to provide structural support and a thermal path to discharge the heat generated by the components housed in the chassis 102. The vapor chamber 104 includes a base plate 106 and a cap portion 108, which covers at least a part of the base plate 106 and attached to the base plate 106 to form a sealed chamber. In some implementations, the vapor chamber is formed by welding the cap portion 108 onto the base plate 106 and the vapor chamber 104 with the base plate 106 is configured to fit within the chassis 102.

In one or more examples, the base plate 106 extends outward beyond the sealed chamber to form an extended portion 110. The extended portion 110 includes a first edge 112, a second edge 114, a third edge 116 and a fourth edge 118. In one or more implementations, the extended portion 106 of the base plate 106 is in the form of a rectangle or square. The first edge 112 of the extended portion 110 is configured to be attached to a sidewall 120 of the chassis 102 and the second edge 114, adjacent to the first edge 112, is in the form of a mechanical flange 122 or a ridge and is provided at the second edge 114 to enable the second edge 114 to be mounted or connected to the chassis 102. The first edge 112 and the second edge 114 of the extended portion 110 attached to the chassis 102 create a flat surface or a floor of a battery compartment 124 within the chassis 102. The extended portion 110 attached to the chassis 102 further provides a thermal path between the vapor chamber 104 and the chassis 102.

FIG. 1B is a rear perspective view of the example electronic device 100 shown in FIG. 1A with the chassis 102 detached from the vapor chamber 104. In one or more implementations, the vapor chamber 104 is formed by attaching the base plate 106, which is typically formed from a thin stainless steel sheet metal with the cap portion 108 using techniques such as welding. In one implementation, the vapor chamber 104 is formed by first fabricating the base plate 106 formed from a 0.05 mm thick stainless steel sheet metal and attaching the cap portion 108 of the vapor chamber 104 onto the base plate 106 using laser welding. In one or more implementations, the vapor chamber 104 has a thickness of 0.35 millimeter (mm) or below. The base plate 106 is typically initially flat, with the cap portion 108 welded onto the base plate 106, and then formed into a specific shape to fit within the chassis 102.

The vapor chamber 104 comprises a first surface arranged proximate to a heat source. A coolant, in a first mode of operation is configured to be evaporated into evaporated coolant at a first region of the vapor chamber 104 by heat absorbed from the heat source, and in a second mode of operation is configured to be condensed in a second region of the vapor chamber 104. The extended portion 110 of the base plate 106, which forms the floor of the battery compartment 124 is typically made substantially flat, which allows a battery to be easily and safely placed on the flat floor of the battery compartment 124. Further, in one or more implementations, one or more edges of the extended portion 110 of the base plate 106 including the first edge 112, the second edge 114, the third edge 116 and the fourth edge 118 extend slightly beyond the cap portion 108, which allows the base plate 106 to be securely mounted on the chassis 102 obviating a reliance on tapes or adhesives, and contributing to reduce the overall thickness of the electronic device 100. In one implementation, the first edge 112 allows the base plate 106 to be securely mounted or placed on the sidewall 120 chassis 102. Typically, an interior of the sidewall 120 of the chassis 102 is provided with one or more interlocking or engaging means to receive and secure the first edge 112 of the base plate 106. In one implementation, the edges 112, 114, 116 and 118 of the extended portion 110 of the base plate 106 are along same plane. In one or more implementations, the edges 112, 114, 116 and 118 of the extended portion 110 of the base plate 106 lie in one or more planes, to prevent the edges coming in contact with the battery placed in the battery compartment 124. Further, the base plate 106 is electrically or conductively connected to the chassis 102 to provide grounding for the electronic device 100. In addition, the base plate 106 forms a mid-plate ground for the one or more antennas adjacent to the base plate 106.

FIG. 1C is a rear perspective view of the example electronic device 100 with the vapor chamber 104 attached to the chassis 102 forming the floor of the battery compartment 124. The second edge 114 of the base plate 106 is provided with the mechanical flange 122, which allows the base plate 106 to be mounted on the chassis 102 or more specifically to a mid-frame portion of the chassis 102. The first edge 112 of the base plate 106 allows the base plate 106 to be securely mounted or placed on the sidewall 120 of the chassis 102. The base plate 106 provides additional structural rigidity to the vapor chamber 104 by attaching to sidewalls 120 of the chassis 102. By supporting the base plate 106 at two edges, the first edge 112 and the second edge 114, to the chassis 102 a structurally strong and substantially flat floor for the battery compartment 124 is formed. In one or more implementations, the extended portion 110 of the base plate 106 covers only a part of the floor of the battery compartment 124, leaving an open space for placement of the flexible connectors electrically connecting various components such as the battery and display module of the example electronic device 100. The open space for placement of the flexible connectors within the battery compartment 124, typically, along the same plane as the extended portion 110 of the base plate 106 allows the floor of the battery compartment 124 to be substantially flat to safely support the battery. Further, the placement of the vapor chamber 104 and base plate 106 design partially covering the floor of the battery compartment 124 facilitate heat transfer from a central location within the electronic device 100 to the chassis 102.

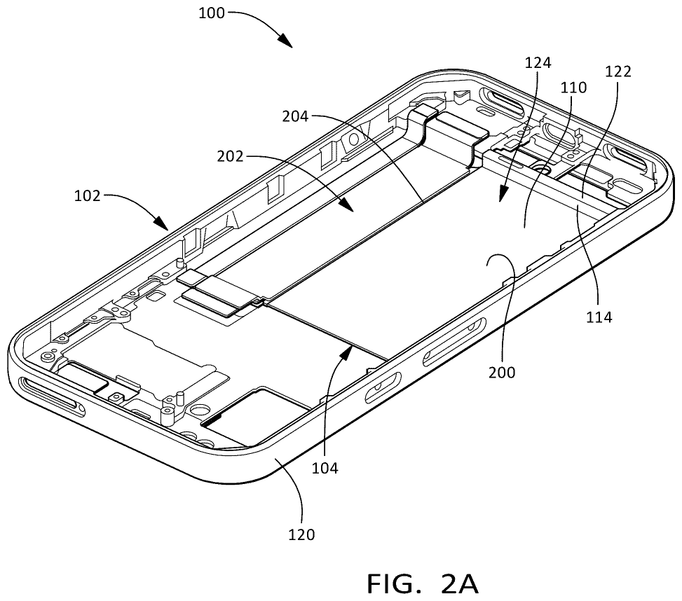

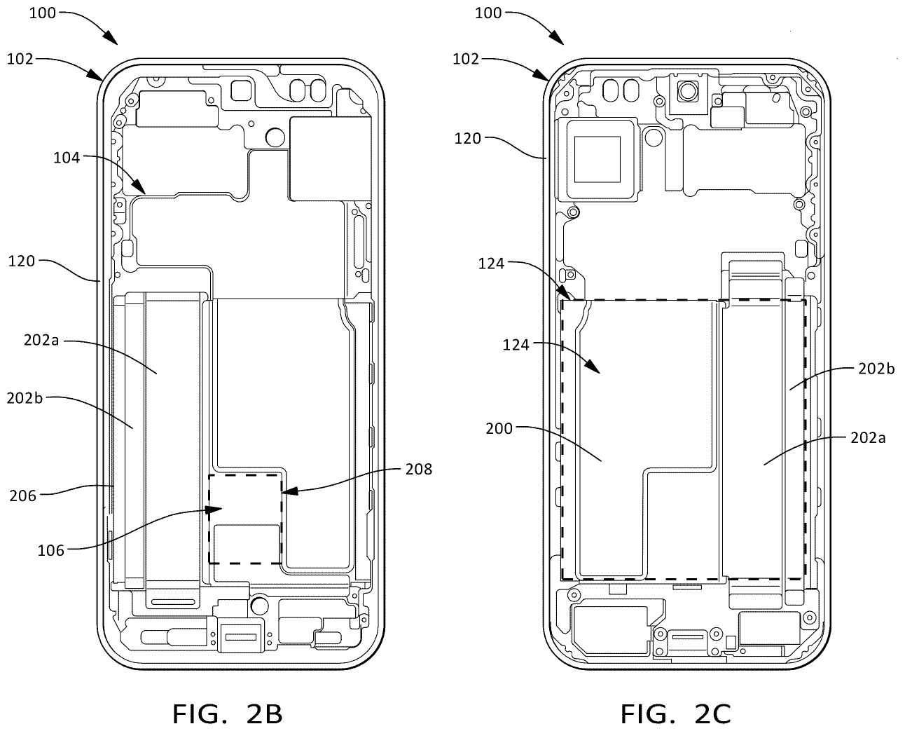

As illustrated in the figures, the vapor chamber 104 can be positioned on a first side of the chassis 102 where a display is positioned. A second side, opposite the first side includes the battery compartment 124 to house the battery. The vapor chamber 106 comprises an extended portion 110 obviating the need for a middle plate and is configured to fit inside the chassis 102 to improve a volumetric efficiency inside the electronic device 102 and enable a thickness (e.g., in the Z-axis) of the electronic device 102 to be reduced. FIG. 2A depicts a perspective view of the example electronic device 100 showing the floor 200 of the battery compartment 124 formed by the extended portion 110 of the base plate 106 and the flexible connectors 202. In one or more implementations, the third edge 116 of the extended portion 110, extending out from the base plate 106 overlaps with a longitudinal edge 204 of the flexible connectors 202. In one implementation, the third edge 116 of the extended portion 110, extending out from the base plate 106 is slightly stepped to receive a longitudinal edge 204 of the flexible connectors 202, thereby preventing hazards that may be caused by the direct contact between the battery placed in the battery compartment 124 and the third edge 116 of the extended portion 110. The flexible connectors 202 and the extended portion 110 of the base plate 106 forms a flat battery compartment 124 with sufficient space, which is obtained by eliminating the need for a mid-plate attached to the chassis 102 in addition to the vapor chamber 104, for placing the battery of selected capacity.

FIG. 2B depicts a front view of the example electronic device 100 shown in FIG. 2A showing the vapor chamber 104 forming a floor of a display module. In one implementation, the flexible connectors 202a, 202b includes a “CJ” flexible connector 202a and an adjacent “RF” flexible connector 202b, which is arranged partially or fully overlapped or side by side with the longitudinal edge 204 of the CJ flexible connector 202a overlapping the extended out third edge 116 of the base plate 106 and obviates the need for additional adhesives or tape to attach to the vapor chamber 104. Further, a longitudinal edge of the RF flexible connector 202b overlaps with the sidewall 120 of the chassis 102. In some cases, a longitudinal edge of the RF flexible connector 202b is arranged in the chassis 102 to overlap with a display trim edge of the display module, which in turn protects the display trim edge.

In one or more implementations, graphite layers or coatings 206 are provided on the sidewalls 120 or on the edges of the extended portion 110 of the base plate 106. The graphite layers 206 are typically 0.03 mm to 0.04 mm and do not significantly increase the overall thickness of the electronic device 100. Furthermore, the graphite layers 206 offer significant advantages such as excellent heat transfer capability for transferring the heat generated by the components including the battery and display module of the electronic device 100 in to the chassis 102 or vapor chamber 104 for dissipation.

Further, in one or more implementations, the extended portion 110 of the base plate 106 is configure to receive an under-display fingerprint scanner (UDFPS) above a designated area 208 (shown as a rectangular region partially filled with graphite layer 206). In one example, the designated area 208 has a thickness same as that of the base plate 106, which is in this case 0.05 mm, without the cap portion 108 covering the area 208, which further gives space for placing the UDFPS. The designated area 208 with a full or partial graphite coating or layer 206 efficiently dissipates or transfer the heat to the vapor chamber 104 or to the chassis 102 for heat dissipation. Further, in some other cases, the mechanical flange provided on the extended portion 110 of the base plate 106 is also coated with the graphite layer 206, to create a thermal path between the vapor chamber 104 and the chassis 102 for heat dissipation.

FIG. 2C depicts a rear view of the example electronic device 100 shown in FIG. 2A showing the extended portion 110 and the plurality of flexible connectors 202a, 202b forming the floor 200 of the battery compartment 124. In one or more implementations, the base plate 106 acts as a thermal barrier between the battery and components generating heat within the electronic device 100. The base plate 106 overlaps with the chassis 102 at a number of locations, eliminating the need for adhesive materials on the vapor chamber 104. The vapor chamber 204 including the extended portion 110 of the base plate 106 replaces a separate mid-frame, thereby reducing overall thickness of the electronic device 100 and facilitates accommodating a larger capacity battery. The vapor chamber 104 attached to the chassis 102 is configured to provide strength and rigidity to the electronic device 100 and therefore aid in protecting the internal components from damage caused by external forces.

In some implementations, the vapor chamber 104 is made of a high thermal conductivity metal materials such as stainless steel or titanium, which helps to quickly dissipate heat. Integrating the vapor chamber 104 and the base plate 106 provides a heat-dissipation channel that also enable the electronic device 100 to be thinner by conserving volume inside the battery compartment 124 in the chassis 102. Further, the area available for thermal dissipation is significantly increased in the electronic device 100 by making use of the continuous available space of the base plate 106 with the extended portion 110 along the X-Y plane.

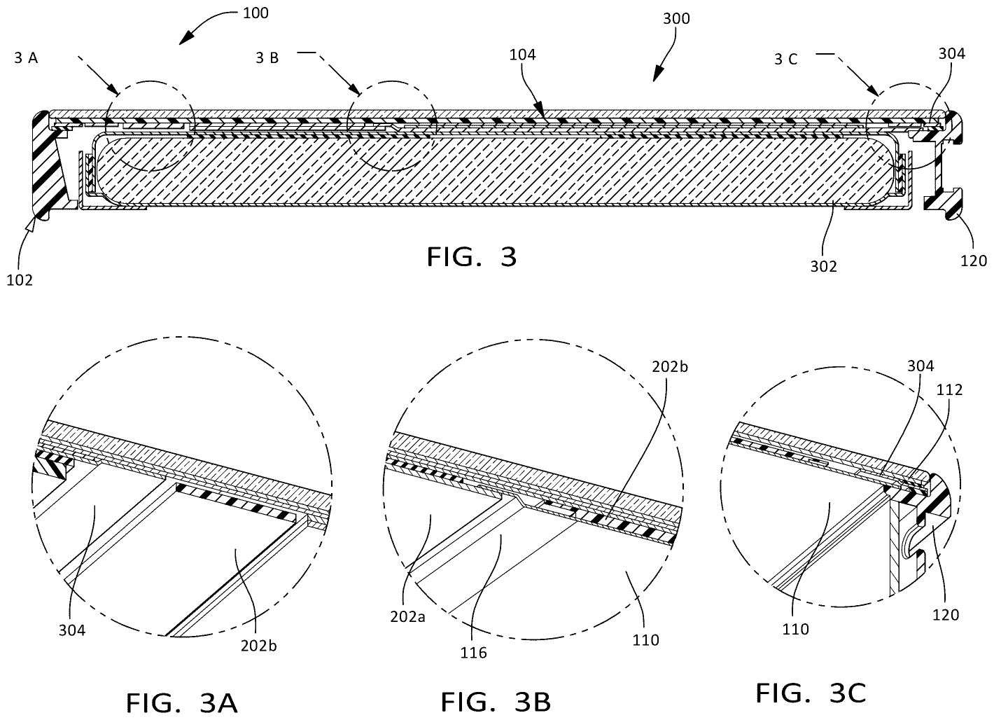

FIG. 3 depicts a side sectional view along a width of the example electronic device 100 (e.g., a smartphone) having a display module or display stack 300, a chassis 102 for housing the components of the electronic device 100 including a battery 302. The display module 300 may be implemented as a display panel stack having a cover layer typically made of glass and a display panel. In some implementations, an opaque border is added to an underside of the cover layer, defining an active area of the display module 300. Alternatively, the chassis 102 surrounding the display module 300, defines the active area. The display module 300 may further include one or more of a touch layer (e.g., touch sensor panel), a polarizer layer (e.g., polarization filters), an adhesive layer (OCA), and/or a protective layer. The protective layer may include one or more sublayers, such as a polymer sublayer, a metallic sublayer (e.g., copper, stainless steel, titanium), a foam pad (e.g., to absorb compressive forces during manufacturing or usage), and an adhesive sublayer. The protective layer can shield the display module 300 from mechanical and electromagnetic forces, as well as from thermal radiation. The display module 300 further includes the panel and the backplate which is typically attached to the vapor chamber 104 or positioned slightly above the vapor chamber 104 for efficient cooling of the display module 300 by transferring the heat through a thermal path to the vapor chamber and to the chassis 102.

FIG. 3A depicts an enraged view of the section 3A of the example electronic device 100 shown in FIG. 3. Section A shows the display trim 304-RF flexible connector 202b of the floor 200 of the battery compartment 124. The RF flexible connector 202b can be, for example, three times thicker than the display trim 304 and overlaps into the display trim 304 protecting the display trim 304 from the battery 302. The floor 200 isolates the battery 302 from the display module 300.

FIG. 3B depicts an enraged view of the section 3B of the example electronic device 100 shown in FIG. 3. The CJ flexible connector 202a overlaps with the stepped edge 116 of the extended portion 110 of the base plate 106, which in turn protects the battery 302 from getting punctured or damaged by the sharp edge 116 of the extended portion 110 of the base plate 106.

FIG. 3C depicts an enraged view of the section 3C of the example electronic device 100 shown in FIG. 3. Section C depicts the edge 112 of the extended portion 110 of the base plate 106 overlapping and mounted onto the sidewall 120 of the chassis 102. The overlapped portion protects the display trim 304 from getting in direct contact with the battery 302. Thus, the structural features mentioned in FIG. 3A-3C protects the display trim 304 from getting in direct contact with the battery 302 without the use of a mid-plate as is the case with the existing designs, which in turn further reduces the overall thickness and facilitates the incorporation of a thicker or higher capacity battery in the battery compartment 124. Further, the elimination of mid-plate allows the inclusion of larger swell gaps of approximately 0.3 mm to 0.4 mm, which accounts for the possible expansion of the battery 302 within the chassis 102 due to heating.

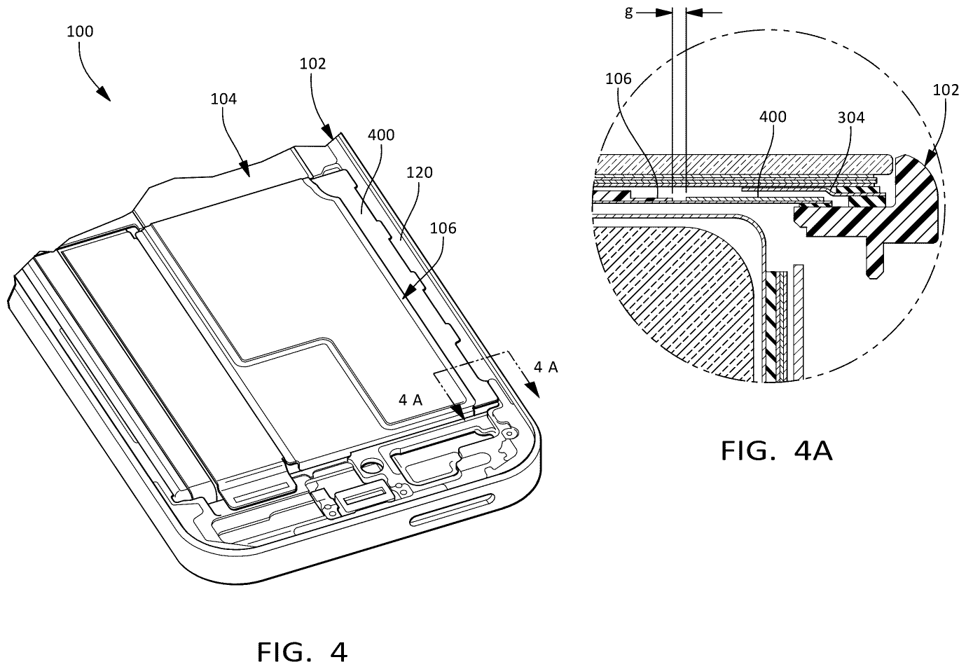

FIG. 4 depicts a perspective view of a bottom portion of the example electronic device 100 showing a part of the chassis 102 and the base plate 106 attached to the vapor chamber 104. In some implementations, the electronic device 100 includes a graphite layer of 0.1 mm along a longitudinal edge 102 overlapping into the chassis 102 or an interior of the sidewall 120 of the chassis upon which the display trim 304 or thermally conductive adhesives are provided to place the display module 300.

FIG. 4A depicts a sectional view of the section 4A of the example electronic device 100 shown in FIG. 4. The graphite layer 400 on the extended portion 110 of the base plate 106 is typically 0.03 mm to 0.04 mm thick. In some implementations, the graphite layer 400 is slightly separated from the edge 112 of the extended portion 110 of the base plate 106, maintaining a distance or gap (g) of approximately 0.4 mm. The thin graphite coating 400 helps to dissipate heat without substantially increasing the overall thickness of the electronic device 100. The graphite layer 400, which is carbon-based, has higher thermal conductivity than stainless steel or aluminum, thereby improves the thermal management of the electronic device 100.

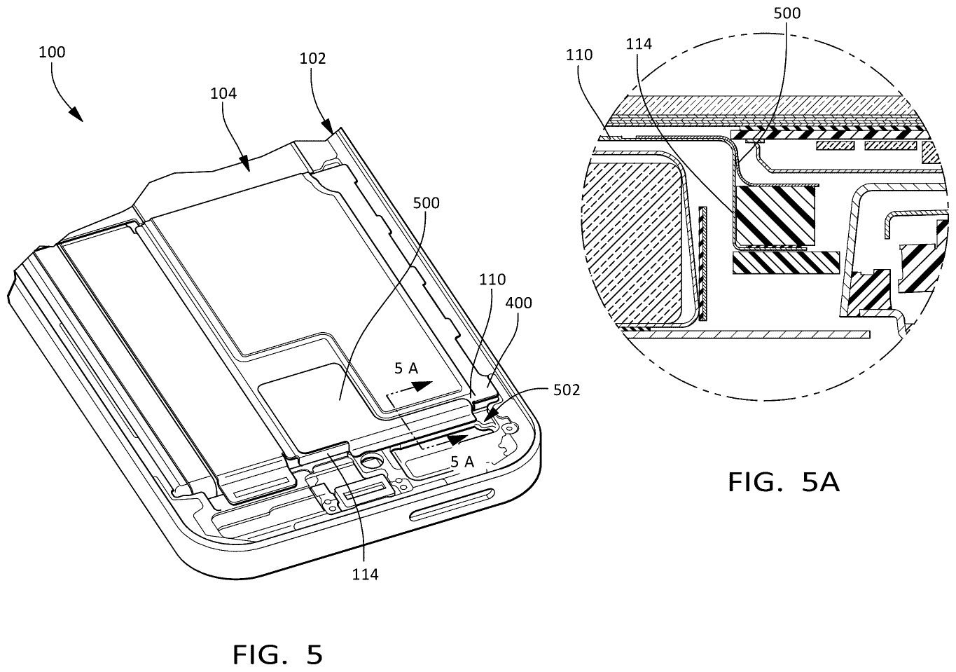

FIG. 5 depicts a perspective view of the example electronic device 100 showing a bottom portion of the chassis 102 and the base plate 106 attached to the vapor chamber 104. A graphite layer or coating 500 is applied to the extended portion 110 of the base plate 106 and the chassis 102. In some implementations, the graphite layer 500 covers at least a portion of the edge 114, including the mechanical flange 122 of the extended portion 110, and extends onto a mid-frame 502 of the chassis 102. Further, the graphite layer 500 enhances thermal conductivity at the designated area 208 beneath the UDFPS, ensuring reliable operation of the UDFPS by preventing overheating of the sensor.

FIG. 5A depicts a sectional view of the section 5A of the example electronic device 100 shown in FIG. 5, which shows how the extended portion 110 of the base plate 106 of the stainless-steel vapor chamber 104 attaches to the bottom side of the chassis 102. The edge 114 includes the mechanical flange 122 formed like a waterfall design and configured to be engaged to the midframe 502 of the chassis 102. In one embodiment the mechanical flange 122 is coated with the graphite layer 500 of thickness 0.03-0.04 mm. In one implementation, the graphite layer 500 is added post vapor chamber installation and is supported on a 50 micrometer mid-plate mounting.

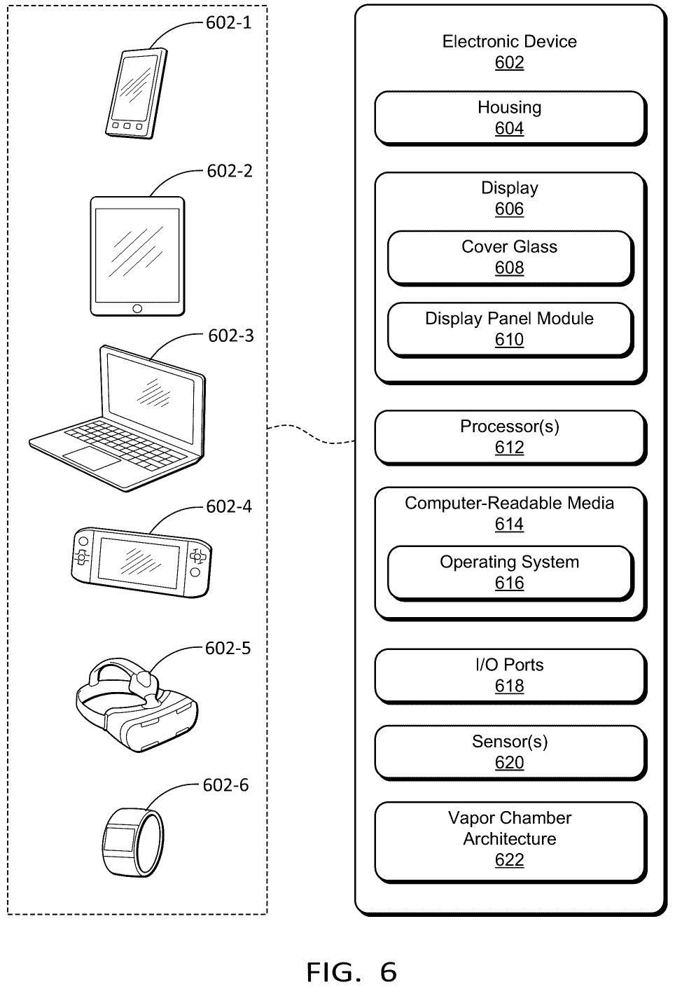

FIG. 6 illustrates an example device diagram of an example electronic device 602 (e.g., example electronic device 100) in which integrated vapor chamber architectures can be implemented. The electronic device 602 may include additional components and interfaces omitted from FIG. 6 for the sake of clarity.

The electronic device 602 can be any of a variety of consumer electronic devices. As non-limiting examples, the electronic device 602 can be a mobile phone 602-1, a tablet device 602-2, a laptop computer 602-3, a portable video game console 602-4, virtual-reality (VR) goggles 602-5, a computerized watch 602-6, and the like.

The electronic device 602 includes a housing 604 and a display 606 (e.g., the display module 300), which define at least one internal cavity within which one or more of a plurality of electronic components may be disposed. In implementations, a middle frame (e.g., the chassis 102) may define one or more portions of the housing 604. As an example, a middle frame can include plastic or metallic walls (e.g., the sidewall 120) that define portions of the housing 604. In additional implementations, a middle frame may support one or more portions of the housing 604. As an example, one or more exterior housing components (e.g., plastic panels) can be attached to the middle frame (e.g., chassis 102). In so doing, the middle frame may physically support the one or more exterior housing components, which define portions of the housing 604. In implementations, the middle frame and/or the exterior housing components may be composed of crystalline or non-crystalline (e.g., metals, plastics) inorganic solids.

The display 606 may include a cover glass 608 and a display panel module 610 (e.g., the display module 300). The cover glass 608 may be composed of a variety of transparent materials including polymers (e.g., plastic, acrylic), glass (e.g., tempered glass, ceramic glass, sapphire), and so forth, forming a three-dimensional shape. For example, the display 606 may be implemented as a plastic organic light-emitting diode (POLED) or as a glass organic light-emitting diode (GOLED). During manufacturing, a bottom face of the cover glass 608 may be bonded (e.g., glued) to the display panel module 610 to protect the display panel module 610 as well as to serve as a barrier to ingress contaminants (e.g., dust, water). The display 606 can include any suitable touch-sensitive display device, such as a touchscreen, a liquid crystal display (LCD), a thin-film transistor (TFT) LCD, an in-place switching (IPS) LCD, a capacitive touchscreen display, an organic light-emitting diode (OLED) display, an active-matrix organic light-emitting diode (AMOLED) display, a super AMOLED display, and so forth. The display 606 may be referred to as a display or a screen, such that digital content may be displayed on-screen.

The display panel module 610 may include a two-dimensional pixel array forming a grid, operably coupled to one or more row-line drivers via electrical traces. The pixel array generates light to create an image on the display 606 upon electrical activation by one or more drivers. As an example, data-line drivers provide voltage data via electrical traces to the pixel array to control a luminance of individual pixels. A section (e.g., a surface) of the display panel module 610 (e.g., a bottom section) may include more circuitry, such as electrical traces and drivers, than other portions of the display panel module 610 (e.g., a top section, a side section). In such a configuration, the display panel module 610 can be configured such that the section having more circuitry is folded or bent in a direction opposite to the cover glass 608. As a result, the display panel module 610 may include a display flex and/or a chip on flex subassembly.

The electronic device 602 may further include one or more processors 612. The processor(s) 612 can include, as non-limiting examples, a system on a chip (SoC), an application processor (AP), a central processing unit (CPU), or a graphics processing unit (GPU). The processor(s) 612 generally executes commands and processes utilized by the electronic device 602 and an operating system installed thereon. For example, the processor(s) 612 may perform operations to display graphics of the electronic device 602 on the display 606 and can perform other specific computational tasks.

The electronic device 602 may also include computer-readable storage media (CRM) 614. The CRM 614 may be a suitable storage device configured to store device data of the electronic device 602, user data, and multimedia data. The CRM 614 may store an operating system 616 that generally manages hardware and software resources (e.g., the applications) of the electronic device 602 and provides common services for applications stored on the CRM 614. The operating system 616 and the applications are generally executable by the processor(s) 612 to enable communications and user interaction with the electronic device 602. One or more processor(s) 612, such as a GPU, perform operations to display graphics of the electronic device 602 on the display 606 and can perform other specific computational tasks. The processor(s) 612 can be single-core or multiple-core processors.

The electronic device 602 may also include input/output (I/O) ports 618. The I/O ports 618 allow the electronic device 602 to interact with other devices or users. The I/O ports 618 may include any combination of internal or external ports, such as universal serial bus (USB) ports, audio ports, Serial ATA (SATA) ports, peripheral component interconnect express (PCIe) based ports or card-slots, secure digital input/output (SDIO) slots, and/or other legacy ports.

The electronic device 602 may further include one or more sensors 620. The sensor(s) 620 can include any of a variety of sensors, such as an audio sensor (e.g., a microphone), a touch-input sensor (e.g., a touchscreen), an image-capture device (e.g., a camera, video-camera), proximity sensors (e.g., capacitive sensors), an under-display fingerprint sensor, or an ambient light sensor (e.g., photodetector). In implementations, the electronic device 602 includes one or more of a front-facing sensor(s) and a rear-facing sensor(s).

The electronic device 602 may also include a vapor chamber architecture 622 (e.g., the vapor chamber 104 with the base plate 106 having the extended portion 110) configured to rapidly dissipate heat from heat sources, such as one or more of the various processors, components, sensors, and displays described above, while reducing the overall thickness of the electronic device.

### CONCLUSION

Unless context dictates otherwise, use herein of the word “or” may be considered use of an “inclusive or,” or a term that permits inclusion or application of one or more items that are linked by the word “or”. Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying Drawings and terms discussed herein may be indicative of one or more items or terms, and thus reference may be made interchangeably to single or plural forms of the items and terms in this written description.

Although aspects of a vapor chamber with a base plate having an extended portion eliminating the need for a mid-plate are described herein with various examples, it is to be understood that the subject of the appended claims is not necessarily limited to the specific techniques, systems, and/or apparatuses described. Further, various aspects are described, and it is to be appreciated that each described aspect can be implemented independently or in connection with one or more other described aspects.

What is claimed is:

1. An electronic device comprising:
a chassis;
a vapor chamber positioned within the chassis, the vapor chamber comprising:
a base plate; and
a cap portion attached to the base plate to form a sealed chamber,
the base plate extending outward beyond the sealed chamber to form an extended portion, the extended portion including a first edge configured to be attached to a sidewall of the chassis and a second edge, adjacent to the first edge, in a form of a mechanical flange configured to be connected to the chassis,
the extended portion configured to form a floor of a battery compartment within the chassis and providing a thermal path between the vapor chamber and the chassis.

2. The electronic device of claim 1, wherein the vapor chamber has a thickness not exceeding 0.35 millimeters.

3. The electronic device of claim 1, wherein the base plate comprises stainless steel sheet metal and the cap portion is attached to the base plate by welding.

4. The electronic device of claim 1, further comprising a graphite layer applied to at least a portion of the base plate or to the chassis.

5. The electronic device of claim 1, wherein the vapor chamber is positioned between a battery and a display module within the chassis.

6. The electronic device of claim 1, wherein the extended portion of the base plate includes a designated area configured to receive an under-display fingerprint sensor.

7. The electronic device of claim 1, wherein the base plate overlaps with the sidewall of the chassis at a plurality of locations effective to provide structural rigidity.

8. The electronic device of claim 1, wherein the base plate is electrically connected to the chassis to provide grounding for the electronic device.

9. The electronic device of claim 1, further comprising at least one antenna, wherein the base plate forms a mid-plate ground for the at least one antenna.

10. The electronic device of claim 1, wherein the electronic device is selected from the group consisting of smartphones, tablets, computers, and smartwatches.
